(19) United States
(12) Patent Application Publication
(10) Pub. No.: US 2006/0237138 A1
(43) Pub. Date: Oct. 26, 2006

(54) Apparatuses and methods for supporting microelectronic devices during plasma-based fabrication processes

(75) Inventor: Shu Qin, Boise, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/115,728

(22) Filed: Apr. 26, 2005

(51) Int. Cl. H01L 21/306; C23C 16/00

(52) U.S. Cl. 156/345.51; 118/728

(57) ABSTRACT

Embodiments of the invention are related to apparatuses and methods for supporting microelectronic devices during plasma-based fabrication processes, including plasma immersion ion implantation, plasma etching, and plasma deposition. In one embodiment, a method for supporting a microfeature workpiece during a fabricating process includes supporting a peripheral portion of a surface of the microfeature workpiece and creating an electrostatic attraction between the microfeature workpiece and a clamping support. In a further embodiment of the invention, the method can include applying electrical pulse(s) to the microfeature workpiece via the peripheral portion of the microfeature workpiece. In yet another embodiment, the workpiece can be located in a chamber and the method can further include introducing a plasma into the chamber and applying electrical pulse(s) to the peripheral portion of the surface of the microfeature workpiece to cause an attractive force between selected particles in the plasma and the microfeature workpiece.

### TECHNICAL FIELD

The present invention relates to apparatuses and methods for supporting microelectronic devices during plasma immersion ion implantation, plasma etching, plasma deposition, and/or other types of plasma-based fabrication processes.

### BACKGROUND

Plasma-based processes such as plasma immersion ion implantation (PIII) are widely used in the manufacturing of workpieces having microfeatures. Electrostatic chucks (ESCs) are often used to support workpieces and provide an electrical potential to the workpieces during plasma-based fabrication processes. Compared to mechanical devices, ESCs are advantageous because they can reduce edge exclusion, provide accurate temperature control, and mitigate particle generation/contamination.

FIG. 1 is a partially schematic top view of an ESC 1 in accordance with the prior art, and FIG. 2 is a partially schematic cross-sectional side view of the ESC 1 of FIG. 1 taken along line 2-2. The ESC 1 includes a clamping support 20, electrical contact pins 2, and lift pins 3. The ESC 1 can be located in a reaction chamber that maintains a low pressure environment and contains a plasma with positively charged ions. The clamping support 20 includes a bipolar electrode 22 encased in a dielectric material. One pole of the bipolar electrode 22 can be connected to a positive portion of a first voltage source 23 and the other pole can be connected to a negative portion of the first voltage source 23. In operation, a clamp voltage Vc is applied to the clamping support 20 by the first voltage source 23 to create an attractive electrostatic force between a workpiece 10 and the bipolar electrode 22 that pulls the backside of the workpiece 10 against the electrical contact pins 2 and lift pins 3.

The electrical contact pins 2 and lift pins 3 can be connected to a second voltage source 13 that provides one or more large negative voltage pulse(s) (e.g., from an AC, DC, or RF source) to the workpiece. The voltage pulse(s) causes current to be conducted through the electrical contact pins 2, the lift pins 3, and the workpiece 10 to drive positive ions in the plasma toward the workpiece 10. The electrical contact pins 2 and the lift pins 3 have sharp tips that can penetrate dielectric materials on the backside of the workpiece 10 when the workpiece 10 is pulled toward the electrode 22 to reduce contact resistance during the application of the voltage pulse(s). The lifting pins 3 also move to raise the workpiece 10 above the clamping support 20 for unloading the workpiece 10 from the clamping support 20 after the implantation process is complete.

An inert gas (e.g., helium) can be applied to the backside of the workpiece to aid in cooling the workpiece during the fabrication process discussed above. For example, the , clamping support 20 can include holes (not shown) through which the inert gas passes to flow across the backside of the workpiece 10 when the workpiece 10 is held in position by the attractive electrostatic force. A seal 25 between the workpiece 10 and the clamping support 20 prevents the pressurized inert gas from escaping between the workpiece 10 and the clamping support 20.

One problem of conventional ESCs is that they can generate particles from the workpiece 10, the electrical contact pins 2, and/or the lift pins 3 during loading, unloading, and/or processing (e.g., pitting can occur on the workpiece 10 or the pins 2 and 3). These particles can contaminate other portions of the workpiece 10. For example, large particles (e.g., greater than 0.4 μm) on the backside of the workpiece 10 can cause the workpiece to have bumps on the front side when loaded into a vacuum chuck. This can produce defects in subsequent photolithography processes.

Another problem of conventional ESCs is that arcing can occur after a voltage pulse from the second voltage source. For example, during the pulse there can be an over-accumulation of positively charged ions on the frontside and backside of the workpiece 10 proximate to the electrical contact pins 2 and the lift pins 3. The over-accumulation of positively charged ions can discharge and arc across the workpiece. Such arcing can damage the photoresist and/or other portions of the device.

Yet another problem associated with the use of ESCs is the complexity of the devices. The construction of the clamping support 20 with the electrical contact pins 2 and the lift pins 3 can be complicated and expensive. Additionally, the location of the electrical contact pins 2 and the lift pins 3, and their associated mechanisms (e.g., actuators used to move the lift pins 3), can interfere with the application of the inert gas to the backside of the workpiece. This results in cooling inefficiencies and non-uniformities.

### BRIEF DESCRIPTION OF THE DRAWINGS

FIG. 1 is a partially schematic top view of an electrostatic chuck in accordance with the prior art.

FIG. 2 is a partially schematic cross-sectional side view of the electrostatic chuck of FIG. 1 taken along line 2-2.

FIG. 3 is a partially schematic side view of a support system with a microfeature support in a raised position for use in fabricating a microfeature workpiece in accordance with embodiments of the invention.

FIG. 4 is a partially schematic top view of the support system of FIG. 3.

FIG. 5 is a partially schematic cross-sectional side view of the support system shown in FIG. 4 taken along line 5-5.

FIG. 6 is a partially schematic top view of the support system of FIG. 3 where the microfeature support has been placed in a lowered position.

FIG. 7 is a partially schematic cross-sectional side view of the support system shown in FIG. 6 taken along line 7-7.

FIG. 8 is a partially schematic top view of the support system shown in FIG. 6 without a microfeature workpiece.

FIG. 9 is a partially schematic top view of a support system for use in fabricating a microfeature workpiece with a microfeature support in accordance with other embodiments of the invention.

FIG. 10 is a partially schematic cross-sectional side view of a system for fabricating a microfeature workpiece using a plasma-based process in accordance with still other embodiments of the invention.

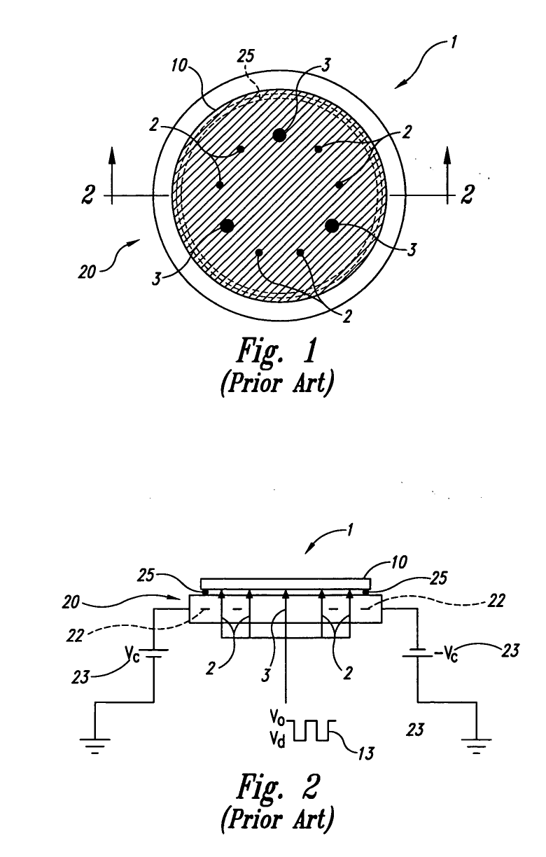

### DETAILED DESCRIPTION

A. Overview/Summary

The following disclosure describes several embodiments of the present invention directed toward apparatuses and methods for supporting microelectronic workpieces and providing an electrical potential uniformly to such workpieces for plasma-based fabrication processes (e.g., PIII, plasma etching, plasma deposition, plasma doping, RIE, dry etching, PECVD, plasma stripping, and PVD). In particular, many specific details of the invention are described below with reference to a single-wafer support for use during a plasma-based fabrication process, but several embodiments can be used in batch systems for processing a plurality of workpieces simultaneously. Moreover, several embodiments can be used for plasma-based processes involving workpieces other than microfeature workpieces. The term “microfeature workpiece” is used throughout to include substrates upon which and/or in which microelectronic devices, micromechanical devices, data storage elements, read/write components, and other features are fabricated. For example, microfeature workpieces can be semiconductor wafers such as silicon or gallium arsenide wafers, glass substrates, insulative substrates, and many other types of materials. Furthermore, the term “gas” is used throughout to include any form of matter that has no fixed shape and will conform in volume to the space available. The term “plasma” is used throughout to include an ionized gas.

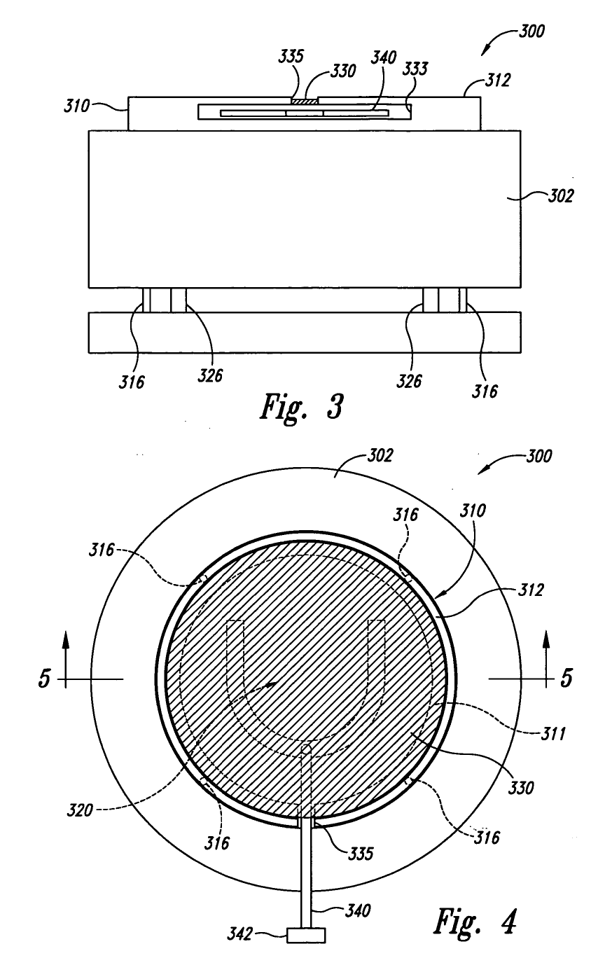

Several embodiments in accordance with the invention are set forth in FIGS. 3-10 and the following text to provide a thorough understanding of particular embodiments of the invention. A person skilled in the art will understand, however, that the invention may have additional embodiments, or that the invention may be practiced without several of the details of the embodiments shown in FIGS. 3-10.

Certain embodiments of the invention are directed toward a support system for use in fabricating a microfeature workpiece that includes a workpiece support having a contact surface configured to support a peripheral portion of a surface of a microfeature workpiece. The system further includes an electrostatic clamping support positioned radially inward of the contact surface of the workpiece support. The clamping support includes a clamping electrode and a dielectric material on a surface of the clamping electrode. In further embodiments of the invention, an electrical source can be operatively couplable to the clamping electrode and/or an electrical source can be operatively coupled to the workpiece support.

Other embodiments of the invention are directed toward a method for supporting a microfeature workpiece during a fabricating process that includes supporting a peripheral portion of a surface of the microfeature workpiece and creating an attractive electrostatic force between the microfeature workpiece and a clamping electrode. The clamping electrode can be carried by a clamping support having a dielectric material positioned between the clamping electrode and the microfeature workpiece. In further aspects of the invention, the method can include applying an electrical pulse (e.g., from an AC, DC, or RF source) to the peripheral portion of the microfeature workpiece via a workpiece support that contacts a peripheral area of the workpiece.

Still other aspects of the invention are directed to a system for fabricating a microfeature workpiece using a plasma-based process that includes a chamber and a workpiece support having a contact surface configured to support a peripheral portion of a surface of a microfeature workpiece. The system further includes an electrostatic clamping support positioned radially inward of the contact surface of the workpiece support. The clamping support includes a clamping electrode and a dielectric material on a surface of the clamping electrode.

Yet other aspects of the invention are directed toward a plasma-based method for processing a microfeature workpiece during fabrication that includes supporting a peripheral portion of a surface of the microfeature workpiece while the microfeature workpiece is located in a chamber and creating an electrostatic attraction between the microfeature workpiece and a clamping electrode. The clamping electrode can be carried by a clamping support having a dielectric material positioned between the clamping electrode and the microfeature workpiece. In a further aspect, the method can include introducing a plasma into the chamber and applying an electrical pulse to the peripheral portion of the surface of the microfeature workpiece via a workpiece support to cause an attractive force between selected particles in the plasma and the microfeature workpiece.

B. Embodiments of Apparatus and Methods for Supporting a Microfeature Workpiece

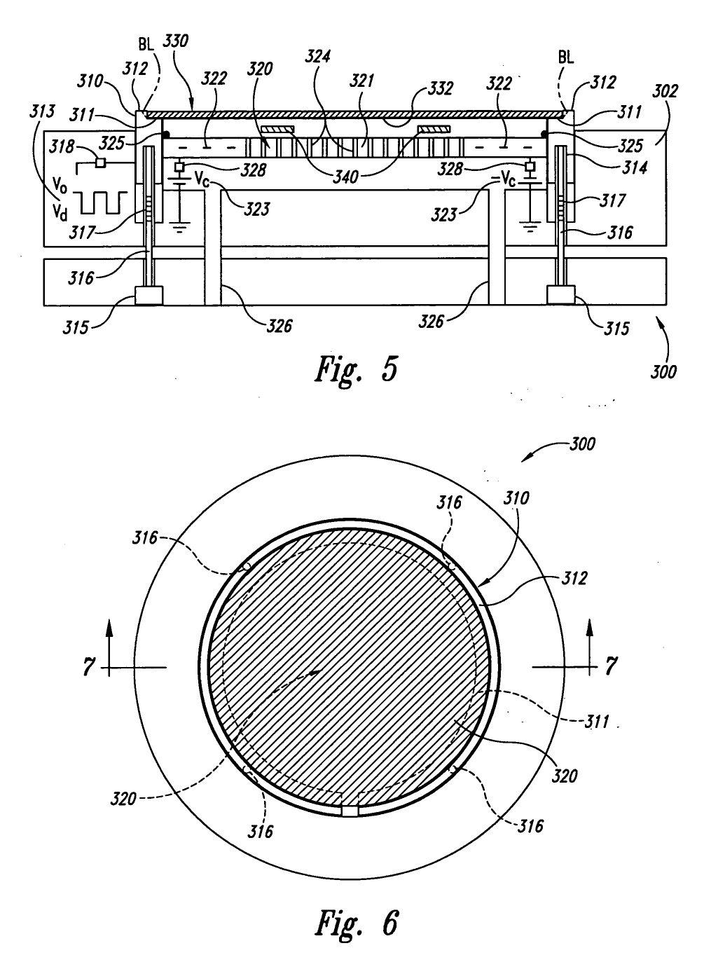

FIG. 3 is a partially schematic side view of a support system 300 for use in fabricating a microfeature workpiece 330 in accordance with embodiments of the invention. FIG. 4 is a partially schematic top view of the support system 300 of FIG. 3, and FIG. 5 is a partially schematic cross-sectional side view of the support system 300 of FIG. 4 taken along line 5-5. The support system 300 includes a housing 302, at least one workpiece support 310 in the housing 302, and at least one clamping support 320 (best shown in FIG. 5) positioned proximate to the workpiece support 310. The workpiece support 310 is preferably configured to provide a pinless edge-contact support that can uniformly apply an electrical potential to the workpiece. In the illustrated embodiment, the clamping support 320 (e.g., an electrostatic support) is configured to create an attractive electrostatic force between the microfeature workpiece 330 and the clamping support 320. The workpiece support 310 is configured to move relative to the housing 302 to raise/lower the microfeature workpiece 330 and to transmit an electrical pulse to the microfeature workpiece 330 without the use of the electrical contact pins and lift pins associated with the ESCs of the prior art.

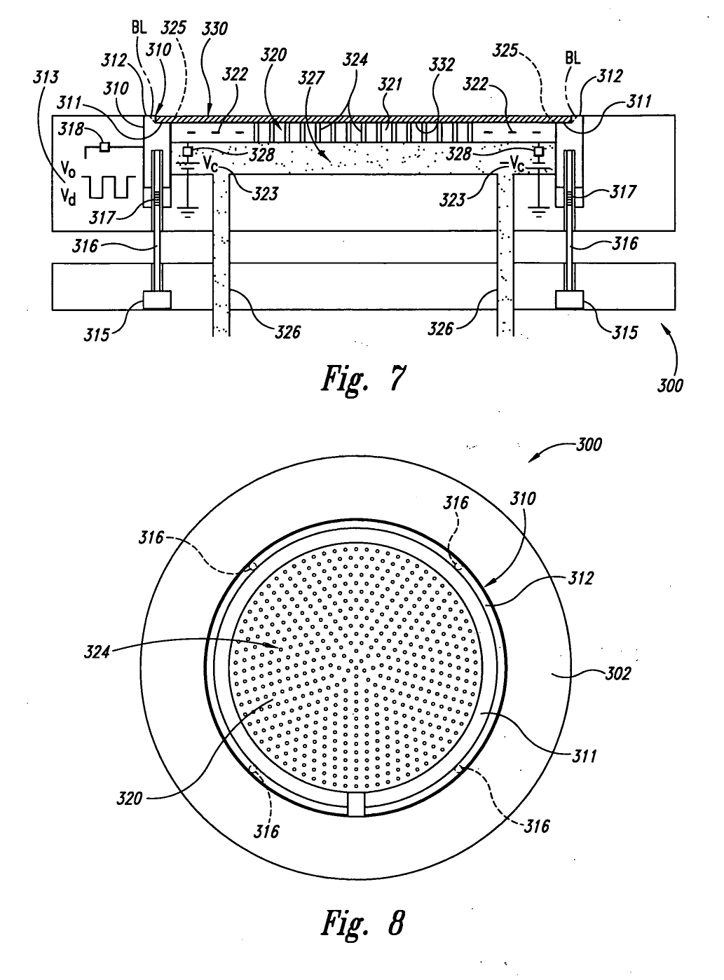

As shown in FIGS. 4 and 5, the illustrated embodiment of the workpiece support 310 extends around a majority of a peripheral portion of a backside 332 of the microfeature workpiece 330 and includes a contact surface 311 (e.g., an annular shoulder or annular shelf) that supports the peripheral portion of the backside 332. The contact surface 311 accordingly provides an edge-contact support in this embodiment. In other embodiments, the workpiece support 310 can extend around a smaller segment of the peripheral portion of the backside 332 of the workpiece 330. The workpiece support 310 can also include a flange 312 around the contact surface 311 of the workpiece support 310. The flange 312 projects away from the contact surface 311 of the workpiece support 310 and is configured to laterally confine the workpiece 330 in a selected position relative to the workpiece support 310. The flange 312, for example, can be approximately perpendicular to the contact surface 311, or the flange 312 can project at an oblique inclined angle relative to the contact surface 311 (as shown by ghosted lines BL in FIGS. 5 and 7). In other embodiments, the workpiece support 310 does not include a flange 312.

The support system 300 can also include one or more support members 316 coupled to one or more optional actuators 315 (FIG. 5) and the workpiece support 310. The support members 316 can be received in a channel 314 (FIG. 5) of the workpiece support, and springs 317 (FIG. 5) or other return devices can be positioned around the support members 316. In one embodiment, the actuators 315 are pneumatic or hydraulic cylinders that lower the workpiece support 310 to a lowered position in which the springs 317 are compressed. The actuators 315 can subsequently raise the workpiece support 310 and/or the springs 317 can raise the workpiece support to a raised position. In the lowered position, the workpiece support 310 carries the microfeature workpiece 330 proximate to (e.g., near or against) the clamping support 320. In the raised position, the workpiece support 310 holds the microfeature workpiece 330 apart from the clamping support 320.

The workpiece support 310 further includes a slot 333 (FIGS. 3 and 5) and a gap 335 for accommodating an end-effector 340 coupled to an automated handling system 342 (FIG. 4). In the raised position shown in FIGS. 3 and 5, the end-effector 340 can be inserted into the slot 333 so that the end-effector 340 is between the microfeature workpiece 330 and the clamping support 320. To load a workpiece onto the workpiece support 310, the end-effector 340 positions the workpiece 330 over the contact surface 311 and then the workpiece support 310 moves upward and/or the end-effector 340 moves downward until an arm portion of the end-effector 340 passes through the gap 335 and the end-effector 340 is aligned with the slot 333. The end-effector 340 is then moved through the slot 333 to withdraw the end-effector 340 from the workpiece support 310. This procedure can be reversed to unload the workpiece 330. In certain embodiments, the end-effector 340 can be manually operated instead of being operated by the automated handling system 342 (e.g., an actuator or robot).

FIG. 6 is a partially schematic top view of the support system 300 of FIG. 3 showing the workpiece support 310 in the lowered position, and FIG. 7 is a partially schematic cross-sectional side view of the support system 300 of FIG. 6 taken along line 7-7. As discussed above, when the workpiece support 310 is in the lowered position, the workpiece 330 is located proximate to the clamping support 320 for being secured in place for a plasma-based process.

Referring to FIGS. 5 and 7, the clamping support 320 has at least one clamping electrode 322 to create an attractive electrostatic force between the workpiece 330 and the clamping support 320. The clamping support 320 also includes a dielectric material 321 positioned between the clamping electrode 322 and the workpiece 330. In the illustrated embodiment, the clamping electrode 322 is encased in the dielectric material (e.g., the clamping support is encased in a dielectric plate). The clamping electrode 322 can be a mono-polar or multi-polar electrode. In the illustrated embodiment, the clamping electrode 322 is bipolar, and the support system 300 further includes (a) a clamping electrical source 323 having a negative voltage potential −Vc coupled to a first pole of the clamping electrode 322 and a positive voltage potential Vc coupled to a second pole of the clamping electrode 322, and (b) one or more switch(es) 328. For example, one switch 328 is positioned between the clamping electrode 322 and the negative voltage potential −Vc, and another switch 328 is positioned between the clamping electrode 322 and the positive voltage potential Vc. When the switches 328 are closed, the clamping electrode 322 is coupled to the clamping electrical source 323 to create an electrostatic force that draws the workpiece 330 toward the clamping support 320. When the workpiece support 310 is in the lowered position shown in FIG. 7, this force securely holds the workpiece 330 in place during processing.

The support system 300 also includes an electrical source 313 (e.g., an implant electrical source) operatively coupled to the workpiece support 310 to apply an electrical potential to the workpiece 330 for certain plasma-based processes (e.g., PIII). Accordingly, in the illustrated embodiment the workpiece support 310 is coupled to the electrical source 313 via a switch 318 to provide one or more electrical pulses to the workpiece 330 during certain plasma-based processes. The contact surface 311 of the workpiece support 310 can be at least approximately flat to provide a consistent contact area between the contact surface 311 and the peripheral portion of the backside 332 of the microfeature workpiece 330. The consistent contact area facilitates a uniform flow of electrical current between the workpiece support 310 and the workpiece 330 when an electrical pulse is provided to the workpiece support 310 (e.g., when the current can flow to a ground via plasma proximate to the workpiece 330). Additionally, the springs 317 resist movement of the workpiece 330 toward the clamping support 320 to ensure that a uniform contact area between the workpiece 330 and the workpiece support 310 is maintained when the clamping support 320 exerts an electrostatic force.

If the backside 332 of the workpiece 330 has a dielectric material layer, the electrical pulse(s) can be transmitted from the contact surface 311 of the workpiece support 310 to the workpiece 330 through the dielectric material without piercing the dielectric material. One aspect of this use is the discovery that the generally flat contact surface 311 of the workpiece support 310, the size of the contact area between the backside 332 of the workpiece 330 and the workpiece support 310, and/or the voltage and amperage of the electrical pulse can cause a temporary electrical breakdown in the dielectric material that allows current to flow between the workpiece support 310 and the workpiece 330. Because the workpiece support 310 can conduct the electrical pulse (e.g., current) to the periphery of the workpiece 330 without piercing the dielectric material, contamination due to pitting in the workpiece 330 can be reduced over that associated with current systems. Additionally, because the contact area between the workpiece 330 and the workpiece support 310 can be larger than that associated with electrical contact pins and lift pins of current systems, there can be less pitting caused by the flow of electrical current during processing (e.g., during the application of an electrical pulse). In other embodiments, the workpiece support 310 is not connected to the electrical source 313.

The support system 300 can further include gas cooling to dissipate heat generated by the processing of the workpiece 330 and/or the clamping of the workpiece 330 with the electrostatic force. Accordingly, a cooling gas (e.g., an inert gas) can be applied (e.g., allowed to contact and/or applied under pressure) to a portion of the clamping support 320 and/or the workpiece 330. In the illustrated embodiment, the support system 300 has passageways 326 and a backside chamber 327 through which cooling gas flows under pressure to the backside of the dielectric material that surrounds the clamping electrode 322 via passageways 326. Referring to FIG. 7, the clamping support 320 can have one or more apertures 324 through the dielectric material 321 for gas to contact the workpiece 330, and the clamping support 320 can also include one or more seals 325 to maintain the pressurized cooling gas against the backside 332 of the workpiece 330.

In FIG. 8, the support system 300 of FIG. 6 is shown without a microfeature workpiece 330. In FIG. 8, the multiple apertures 324 that allow the cooling gas to contact the workpiece 330 are visible. In other embodiments, the clamping support 320 can include more or fewer apertures 324. In certain embodiments, the clamping support is configured to act as a heat sink (e.g., with an internal fluid cooling system) and has no apertures 324. In other embodiments, the support system 300 does not include any seals.

A feature of embodiments discussed above is that the workpiece support can conduct electrical current to the microfeature workpiece without penetrating the workpiece. Additionally, the workpiece support can provide a larger and more consistent contact area between the workpiece in the workpiece support than that available with the electrical contact pins and lift pins of the current systems. This can result in less pitting, particle generation, and/or contamination during the loading, processing, and unloading of a workpiece than when using current systems. Additionally, the larger and more consistent contact area can reduce the amount of arcing as compared to systems using electrical contact pins and lift pins to conduct current to the workpiece. Furthermore, if arcing and/or contamination does occur with embodiments of the invention discussed above, it can be more likely to occur near the peripheral portions of the microfeature workpiece (e.g., proximate to the surface of the workpiece support supporting the workpiece), where it is generally less harmful and/or easier to repair. An advantage of these features is that workpieces can be fabricated with fewer defects, increasing throughput and reducing the cost of producing microfeature workpieces.

Another feature of embodiments discussed above is that the support system can be less complex than current systems that use electrical contact pins and lift pins. Additionally, because there are no electrical contact pins, lift pins, and associated mechanisms located in the center of the clamping support, the clamping support can be configured to provide better cooling for the workpiece as compared to current systems (e.g., the cooling apertures can be better placed and/or more cooling apertures can be used). An advantage of this feature is that the support system can be cheaper to produce and less expensive to maintain than current systems. Another advantage of this feature is that the support system can provide more efficient cooling and/or better cooling uniformity across the workpieces during workpiece processing as compared to current systems.

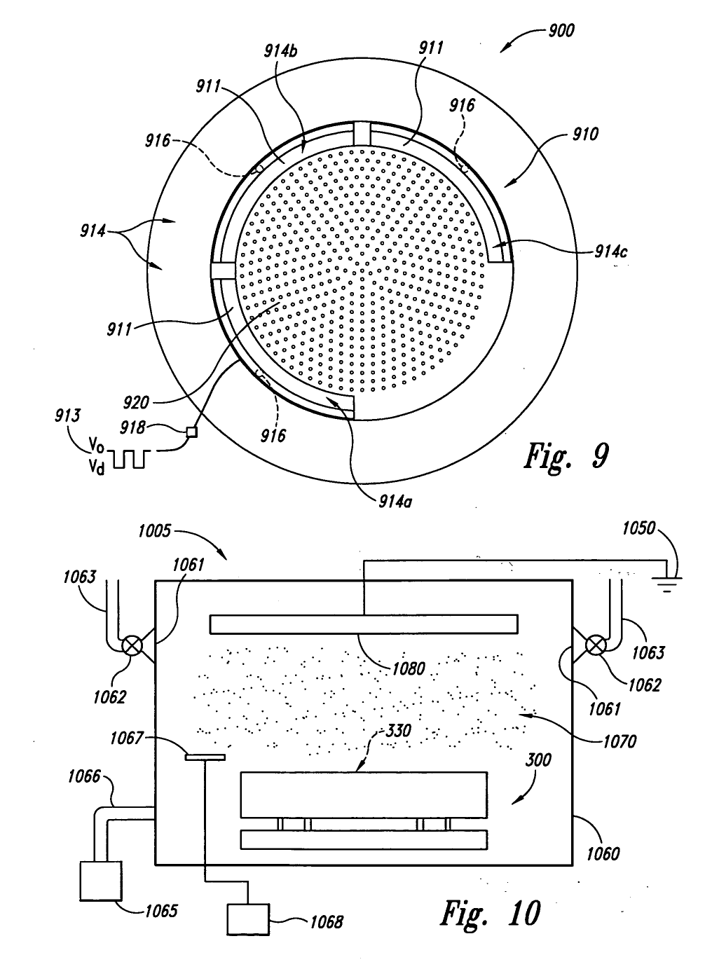

In other embodiments, the support system can have other arrangements. For example, FIG. 9 is a partially schematic top view of a support system 900 for use in fabricating the microfeature workpiece in accordance with another embodiment of the invention. The support system 900 includes a clamping support 920 and a workpiece support 910 (e.g., an annular workpiece support) having a contact surface 911 configured to support a microfeature workpiece in a manner similar to that discussed above with reference to FIGS. 3-8. The contact surface 911 of the workpiece support 910 includes multiple segments 914. In the illustrated embodiment, the contact surface 911 includes a first segment 914a, a second segment 914b, and a third segment 914c. In other embodiments, the contact surface 911 of the workpiece support 910 can include more or fewer segments 914. Similar to the workpiece support discussed above with reference to FIGS. 3-8, the workpiece support 910 includes supports 916 coupled to one or more actuators (not shown in FIG. 9) and is movable between a raised and lowered position. Additionally, the workpiece support 910 is couplable to an implant electrical source 913 via a switch 918 to conduct electrical current to the workpiece during certain plasma-based processes (e.g., PIII).

The support system 900 can provide a larger and more consistent contact area between the workpiece support 910 and a workpiece than is provided by the electrical contact pins and lift pins of current systems. Additionally, the support system 900 can be less complex to make and operate. Accordingly, embodiments of the invention discussed with reference to FIG. 9 can have advantages similar to those discussed above with reference to FIGS. 3-8.

Although the workpiece support 910 is configured to support a circular microfeature workpiece, in other embodiments the workpiece support 910 can be configured to support workpieces having other shapes. Additionally, although the support systems shown in FIGS. 3-9 are oriented to allow a workpiece to be loaded and unloaded from the top, in other embodiments the support systems can have other orientations. In certain embodiments, the workpiece support is not coupled to actuating devices and is raised and lowered manually or only has a single position relative to the clamping support.

C. Embodiments of Apparatus and Methods for Fabricating a Microfeature Workpiece

FIG. 10 is a partially schematic cross-sectional side view of a system 1005 for fabricating a microfeature workpiece 330 using a plasma-based process in accordance with still other embodiments of the invention. In the illustrated embodiment, the fabrication system 1005 includes a chamber 1060 and a support system 300 similar to the support system shown in FIGS. 3-8. In other embodiments, other support systems can be used (e.g., the support system 900 shown in FIG. 9). In still other embodiments, the fabrication system 1005 can include multiple support systems.

In the illustrated embodiment, the chamber 1060 includes a pressure control device 1065, two gas distributors 1061, a plasma-generating device 1067, and an anode 1080. The pressure control device 1065 can be coupled to the chamber 1060 via a passageway 1066. The pressure control device 1065 can be configured to maintain an interior of the chamber at a selected pressure, for example, a low-pressure (e.g., 10⁻³ torr) that facilitates certain plasma-based processes.

In FIG. 10, the two gas distributors 1061 are coupled to passageways 1063 via valves 1062 and are configured to distribute gas into the chamber 1060. The plasma generating device 1067 can be coupled to a controller and/or power supply 1068 and configured to create plasma 1070 from the gas. For example, the plasma generating device 1067 can include a “cold-cathode.”An electric field can be created between the cold-cathode and the anode 1080, generating positively charged ions. In other embodiments, the chamber 1060 can have other arrangements. For example, in certain embodiments, the chamber can include more or fewer gas distributors 1061. In other embodiments, the gas distributors 1061 can distribute plasma (e.g., plasma that has been created outside the chamber 1060) into the chamber 1060, and the chamber does not include a plasma generating device 1067. In still other embodiments, a negative potential applied to the workpiece 330 via the support system 300 can create an electric field between the workpiece 330 and the anode 1080, generating positively charged ions, and thereby generating a plasma. In yet other embodiments, other methods can be used to create plasma (e.g., an RF source, a microwave source, an ICP source, and/or an ECR source placed inside or proximate to the chamber 1060).

As discussed above, the support system 300 is configured to carry a workpiece 330 during a plasma-based process. In the illustrated embodiment, the support system 300 includes a clamping support that creates an attractive electrostatic force between the clamping support and the workpiece 330. In certain embodiments (e.g., during a PIII), the support system 300 includes a workpiece support configured to conduct electrical current to a ground 1050 through the workpiece 330 and the anode 1080 to cause an attractive force between selected particles (e.g., positively charged ions) in the plasma 1070 and the workpiece 330. For example, in a PIII process the attractive force can cause ions from the plasma to be implanted in the workpiece 330.

The support system 300 can provide a larger and more uniform contact area between the workpiece support and the workpiece 330 than is provided by the electrical contact pins and lift pins of current systems. Additionally, the support system 300 can be less complex to make and operate. Accordingly, embodiments of the invention discussed with reference to FIG. 10 can have similar advantages to those discussed above with reference to FIGS. 3-9.

From the foregoing, it will be appreciated that specific embodiments of the invention have been described herein for purposes of illustration, but that various modifications may be made without deviating from the invention. For example, aspects of the invention described in the context of particular embodiments may be combined or eliminated in other embodiments. Although advantages associated with certain embodiments of the invention have been described in the context of those embodiments, other embodiments may also exhibit such advantages. Additionally, not all embodiments need necessarily exhibit such advantages to fall within the scope of the invention. Accordingly, the invention is not limited except as by the appended claims.

We claim:

1. A support system for use in fabricating a microfeature workpiece, comprising:
a workpiece support having a contact surface configured to support a peripheral portion of a surface of a microfeature workpiece; and
an electrostatic clamping support positioned radially inward of the contact surface of the workpiece support, wherein the clamping support includes a clamping electrode and a dielectric material on a surface of the clamping electrode.

2. The system of claim 1 wherein the contact surface of the workpiece support comprises an annular shoulder to support the peripheral portion of the surface of the microfeature workpiece.

3. The system of claim 1 wherein the workpiece support includes multiple arcuate segments having curved contact surfaces positioned in a circle to support the peripheral portion of the surface of the microfeature workpiece.

4. The system of claim 1 wherein the contact surface of the workpiece support comprises an annular shelf that extends around a majority of the periphery of the surface of the microfeature workpiece.

5. The system of claim 1 wherein the contact surface of the workpiece support is at least approximately flat.

6. The system of claim 1 wherein the workpiece support is configured to move between a lowered position and a raised position, in the lowered position the workpiece support being positioned to carry the microfeature workpiece proximate to the dielectric material of the clamping support and in the raised position the workpiece support being positioned to carry the microfeature workpiece apart from the clamping support.

7. The system of claim 1, further comprising at least one actuator coupled to the workpiece support, the actuator being positioned to move the workpiece support between a lowered position and a raised position, wherein in the lowered position the workpiece support is positioned to carry the microfeature workpiece proximate to the dielectric material of the clamping support and in the raised position the workpiece support is positioned to carry the microfeature workpiece apart from the clamping support.

8. The system of claim 1 wherein the workpiece support is configured to move between a lowered position and a raised position, in the lowered position the workpiece support being positioned to carry the microfeature workpiece proximate to the dielectric material of the clamping support so that the workpiece support and the clamping support carry the microfeature workpiece and in the raised position the workpiece support being positioned to carry the microfeature workpiece apart from the clamping support.

9. The system of claim 1 wherein the workpiece support is configured to move between a lowered position and a raised position, in the lowered position the workpiece support being positioned to carry the microfeature workpiece proximate to the dielectric material of the clamping support and in the raised position the workpiece support being positioned to carry the microfeature workpiece apart from the clamping support, and wherein the system further comprises an end-effector positionable between the clamping support and the microfeature workpiece when the microfeature workpiece is carried by the workpiece support in the raised position.

10. The system of claim 1 wherein the workpiece support is configured to move between a lowered position and a raised position, in the lowered position the workpiece support being positioned to carry the microfeature workpiece proximate to the dielectric material of the clamping support and in the raised position the workpiece support being positioned to carry the microfeature workpiece apart from the clamping support, and wherein the system further comprises a robotic end-effector positionable between the clamping support and the microfeature workpiece when the microfeature workpiece is carried by the workpiece support in the raised position.

11. The system of claim 1, further comprising an electrical source operatively couplable to the clamping electrode.

12. The system of claim 1, further comprising an electrical source operatively couplable to the workpiece support.

13. The system of claim 1, further comprising an electrical source operatively couplable to the workpiece support, the workpiece support configured to conduct electrical current to the peripheral portion of the surface of the microfeature workpiece when the microfeature workpiece is carried by the workpiece support and the electrical source is coupled to the workpiece support.

14. The system of claim 1 wherein the peripheral portion of the surface of the microfeature workpiece includes a first portion of the microfeature workpiece, and wherein the clamping support includes at least one aperture positioned to allow a cooling gas to contact a second portion of the surface of the microfeature workpiece when the microfeature workpiece is carried proximate to the clamping support by the workpiece support.

15. The system of claim 1, further comprising a return device positioned to resist movement of the microfeature workpiece toward the clamping support when the microfeature workpiece is supported by the workpiece support.

16. The system of claim 1 wherein the workpiece support includes a flange projecting away from the contact surface at an angle that is at least approximately perpendicular to the contact surface.

17. The system of claim 1 wherein the workpiece support includes a flange projecting away from the contact surface at an angle that is oblique to the contact surface.

18. The system of claim 1 wherein the workpiece support includes a gap in the contact surface and a slot below the contact surface, and wherein the workpiece support is configured to move between a lowered position and a raised position, in the lowered position the workpiece support being positioned to carry the microfeature workpiece proximate to the dielectric material of the clamping support and in the raised position the workpiece support being positioned to carry the microfeature workpiece apart from the clamping support, and wherein the system further comprises an end-effector having an arm, the slot being configured to allow the end-effector to pass through the slot to be positionable between the clamping support and the microfeature workpiece when the microfeature workpiece is carried by the workpiece support in the raised position and the gap being configured to allow the arm of the end-effector to pass through the gap.

19. A support system for use in fabricating a microfeature workpiece, comprising:
an annular workpiece support having an annular contact surface configured to contact a peripheral portion of a surface of a microfeature workpiece;
an electrostatic support having a dielectric plate within the annular workpiece support and a clamping electrode in the dielectric plate; and
an electrical source operatively couplable to the clamping electrode to cause an attractive electrostatic force between the electrostatic support and the microfeature workpiece when a microfeature workpiece is carried proximate to the electrostatic support by the workpiece support and the electrical source is coupled to the clamping electrode.

20. The system of claim 19 wherein the workpiece support is configured to move between a lowered position and a raised position, in the lowered position the workpiece support being positioned to carry the microfeature workpiece proximate to the dielectric material of the electrostatic support and in the raised position the workpiece support being positioned to carry the microfeature workpiece apart from the electrostatic support.

21. The system of claim 19, further comprising at least one actuator coupled to the workpiece support, the actuator being positioned to move the workpiece support between a lowered position and a raised position, wherein in the lowered position the workpiece support is positioned to carry the microfeature workpiece proximate to the dielectric material of the electrostatic support and in the raised position the workpiece support is positioned to carry the microfeature workpiece apart from the electrostatic support.

22. The system of claim 19 wherein the workpiece support is configured to move between a lowered position and a raised position, in the lowered position the workpiece support being positioned to carry the microfeature workpiece proximate to the dielectric material of the electrostatic support and in the raised position the workpiece support being positioned to carry the microfeature workpiece apart from the electrostatic support, and wherein the system further comprises an end-effector positionable between the electrostatic support and the microfeature workpiece when the microfeature workpiece is carried by the workpiece support in the raised position.

23. The system of claim 19 wherein the electrical source operatively couplable to the clamping electrode includes a first electrical source, and wherein the system further comprises a second electrical source operatively couplable to the workpiece support.

24. The system of claim 19 wherein the electrical source operatively couplable to the clamping electrode includes a first electrical source, and wherein the system further comprises a second electrical source operatively couplable to the workpiece support, the workpiece support being configured to conduct electrical current to the peripheral portion of the surface of the microfeature workpiece when the microfeature workpiece is carried by the workpiece support and the second electrical source is coupled to the workpiece support.

25. The system of claim 19 wherein the workpiece support includes multiple annular segments to support the peripheral portion of the surface of the microfeature workpiece.

26. The system of claim 19 wherein the contact surface of the workpiece support comprises an annular shoulder to support the peripheral portion of the surface of the microfeature workpiece.

27. The system of claim 19 wherein the peripheral portion of the surface of the microfeature workpiece includes a first portion of the microfeature workpiece, and wherein the electrostatic support includes at least one aperture positioned to allow a cooling gas to contact a second portion of the surface of the microfeature workpiece when the microfeature workpiece is carried proximate to the electrostatic support by the workpiece support.

28. The system of claim 19 wherein the workpiece support includes a gap in the contact surface and a slot below the contact surface, and wherein the workpiece support is configured to move between a lowered position and a raised position, in the lowered position the workpiece support being positioned to carry the microfeature workpiece proximate to the dielectric material of the electrostatic support and in the raised position the workpiece support being positioned to carry the microfeature workpiece apart from the electrostatic support, and wherein the system further comprises an end-effector having an arm, the slot being configured to allow the end-effector to pass through the slot to be positionable between the electrostatic support and the microfeature workpiece when the microfeature workpiece is carried by the workpiece support in the raised position and the gap being configured to allow the arm of the end-effector to pass through the gap.

29. A support system for use in fabricating a microfeature workpiece, comprising:
support means for supporting a peripheral portion of a surface of the microfeature workpiece; and
an electrostatic clamping support positioned proximate to the support means, wherein the clamping support includes a clamping electrode and a dielectric material on a surface of the clamping electrode.

30. The system of claim 29 wherein the support means is configured to move between a lowered position and a raised position, in the lowered position the support means being positioned to carry the microfeature workpiece proximate to the dielectric material of the clamping support and in the raised position the support means being positioned to carry the microfeature workpiece apart from the clamping support.

31. The system of claim 29, further comprising at least one actuator coupled to the support means, the actuator being positioned to move the support means between a lowered position and a raised position, wherein in the lowered position the support means is positioned to carry the microfeature workpiece proximate to the dielectric material of the clamping support and in the raised position the support means is positioned to carry the microfeature workpiece apart from the clamping support.

32. The system of claim 29 wherein the support means is movable between a lowered position and a raised position, in the lowered position the support means being positioned to carry the microfeature workpiece proximate to the dielectric material of the clamping support and in the raised position the support means being positioned to carry the microfeature workpiece apart from the clamping support, and wherein the system further comprises an end-effector positionable between the clamping support and the microfeature workpiece when the support means carries the microfeature workpiece in the raised position.

33. The system of claim 29, further comprising an electrical source operatively couplable to the clamping electrode.

34. The system of claim 29, further comprising an electrical source operatively couplable to the support means.

35. The system of claim 29, further comprising an electrical source operatively couplable to the support means, the support means configured to conduct electrical current to the peripheral portion of the surface of the microfeature workpiece when the microfeature workpiece is carried by the support means and the electrical source is coupled to the support means.

36. A system for fabricating a microfeature workpiece using a plasma-based process, comprising:
a chamber;
a workpiece support having a contact surface configured to support a peripheral portion of a surface of a microfeature workpiece; and
an electrostatic clamping support positioned radially inward of the contact surface of the workpiece support, wherein the clamping support includes a clamping electrode and a dielectric material on a surface of the clamping electrode.

37. The system of claim 36 wherein the chamber includes a gas distributor.

38. The system of claim 36 wherein the chamber includes a plasma generating device.

39. The system of claim 36, further comprising plasma contained by the chamber.

40. The system of claim 36 wherein the chamber includes a pressure control device.

41. The system of claim 36, further comprising an anode contained by the chamber.

42. The system of claim 36, further comprising an electrical source operatively couplable to the clamping electrode.

43. The system of claim 36, further comprising an electrical source operatively couplable to the workpiece support.

44. The system of claim 36, further comprising an electrical source operatively couplable to the workpiece support, the workpiece support configured to conduct electrical current to the peripheral portion of the surface of the microfeature workpiece when the microfeature workpiece is carried by the workpiece support and the electrical source is coupled to the workpiece support.

45. The system of claim 36, further comprising:
plasma contained by the chamber; and
an electrical source operatively couplable to the workpiece support, the workpiece support configured to conduct electrical current to the peripheral portion of the surface of the microfeature workpiece to cause an attractive force between selected particles in the plasma and the microfeature workpiece when the microfeature workpiece is carried by the workpiece support and the implant source is coupled to the workpiece support.

46. A method for supporting a microfeature workpiece during a fabricating process, comprising:
supporting a peripheral portion of a surface of the microfeature workpiece; and
creating an attractive electrostatic force between the microfeature workpiece and a clamping electrode, the clamping electrode being carried by a clamping support having a dielectric material positioned between the clamping electrode and the microfeature workpiece.

47. The method of claim 46, further comprising applying an electrical pulse to the microfeature workpiece via the peripheral portion of the microfeature workpiece.

48. The method of claim 46 wherein supporting a peripheral portion of a surface of the microfeature workpiece includes supporting a first portion of a surface of the microfeature workpiece, and wherein the method further comprises applying a cooling gas to a second portion of the surface of the microfeature workpiece.

49. The method of claim 46 wherein supporting a peripheral portion of a surface of the microfeature workpiece includes supporting a peripheral portion of a surface of the microfeature workpiece with a workpiece support, and wherein the method further comprises moving the workpiece support between a lowered position and a raised position, in the lowered position the workpiece support being positioned to carry the microfeature workpiece proximate to the dielectric material of the clamping support and in the raised position the workpiece support being positioned to carry the microfeature workpiece apart from the clamping support.

50. The method of claim 46 wherein supporting a peripheral portion of a surface of the microfeature workpiece includes supporting a peripheral portion of a surface of the microfeature workpiece with a workpiece support, and wherein the method further comprises:
placing the microfeature workpiece on the workpiece support, the workpiece support being in a raised position where the workpiece support is positioned to carry the microfeature workpiece apart from the clamping support;
moving the workpiece support to a lowered position where the workpiece support is positioned to carry the microfeature workpiece proximate to the dielectric material of the clamping support;
moving the workpiece support to the raised position; and
removing the microfeature workpiece from the workpiece support.

51. The method of claim 46 wherein supporting a peripheral portion of a surface of the microfeature workpiece includes supporting a peripheral portion of a surface of the microfeature workpiece with a workpiece support, and wherein the method further comprises:
placing the microfeature workpiece on the workpiece support using an end-effector, the workpiece support being in a raised. position where the workpiece support is positioned to carry the microfeature workpiece apart from the clamping support;
moving the workpiece support to a lowered position where the workpiece support is positioned to carry the microfeature workpiece proximate to the dielectric material of the clamping support;
moving the workpiece support to the raised position; and
removing the microfeature workpiece from the workpiece support using an end-effector.

52. The method of claim 46 wherein supporting a peripheral portion of a surface of the microfeature workpiece includes supporting a peripheral portion of a surface of the microfeature workpiece with a workpiece support, and wherein the method further comprises:
placing the microfeature workpiece on the workpiece support, the workpiece support being in a raised position where the workpiece support is positioned to carry the microfeature workpiece apart from the clamping support;
moving the workpiece support to a lowered position where the workpiece support is positioned to carry the microfeature workpiece proximate to the dielectric material of the clamping support;
applying an electrical pulse to the microfeature workpiece via the peripheral portion of the microfeature workpiece;
moving the workpiece support to the raised position; and
removing the microfeature workpiece from the workpiece support.

53. A method for making a support system for use in fabricating a microfeature workpiece, comprising:
configuring a workpiece support to support a peripheral portion of a surface of the microfeature workpiece; and
positioning a clamping support having a dielectric material proximate to the workpiece support, the clamping support carrying a clamping electrode, the clamping electrode positioned so that when the peripheral portion of the surface of the microfeature workpiece is supported by the workpiece support the dielectric material is located between the clamping electrode and the microfeature workpiece.

54. The method of claim 53 wherein configuring a workpiece support to support a peripheral portion of a surface of the microfeature workpiece includes configuring a workpiece support to extend around a majority of the periphery of the surface of the microfeature workpiece.

55. The method of claim 53, further comprising configuring the workpiece support to move between a lowered position and a raised position, wherein in the lowered position the workpiece support is positioned to carry the microfeature workpiece proximate to the dielectric material of the clamping support and in the raised position the workpiece support is positioned to carry the microfeature workpiece apart from the clamping support.

56. The method of claim 53, further comprising:
configuring the workpiece support to move between a lowered position and a raised position, wherein in the lowered position the workpiece support is positioned to carry the microfeature workpiece proximate to the dielectric material of the clamping support and in the raised position the workpiece support is positioned to carry the microfeature workpiece apart from the clamping support; and
coupling at least one actuator to the workpiece support, the actuator being positioned to move the workpiece support between the lowered position and the raised position.

57. The method of claim 53, further comprising:
configuring the workpiece support to move between a lowered position and a raised position, wherein in the lowered position the workpiece support is positioned to carry the microfeature workpiece proximate to the dielectric material of the clamping support and in the raised position the workpiece support is positioned to carry the microfeature workpiece apart from the clamping support; and
configuring an end-effector to at least one of place the microfeature workpiece on the workpiece support and remove the microfeature workpiece from the workpiece support when the workpiece support is in the raised position.

58. The method of claim 53, further comprising configuring the clamping electrode to be operatively couplable to an electrical source.

59. The method of claim 53, further comprising configuring the workpiece support to be operatively couplable to an electrical source.

60. The method of claim 53 wherein configuring a workpiece support to support a peripheral portion of a surface of the microfeature workpiece includes configuring the workpiece support to conduct electrical current to the peripheral portion of the surface of the microfeature workpiece when the microfeature workpiece is carried by the workpiece support and the workpiece support is coupled to an electrical source, and wherein the method further comprises configuring the workpiece support to be operatively couplable to the electrical source.

61. The method of claim 53 wherein configuring a workpiece support to support a peripheral portion of a surface of the microfeature workpiece includes configuring a workpiece support to support a first portion of the surface of the microfeature workpiece, and wherein the method further includes configuring the clamping support to allow a cooling gas to contact a second portion of the surface of the microfeature workpiece when the microfeature workpiece is carried proximate to the clamping support by the workpiece support.

62. The method of claim 53, further comprising configuring a return device to resist movement of the microfeature workpiece toward the clamping support when the microfeature workpiece is supported by the workpiece support.

63. A plasma-based method for processing a microfeature workpiece during fabrication, comprising:
supporting a peripheral portion of a surface of the microfeature workpiece while the microfeature workpiece is located in a chamber; and
creating an electrostatic attraction between the ,.microfeature workpiece and a clamping electrode, the clamping electrode being carried by a clamping support having a dielectric material positioned between the clamping electrode and the microfeature workpiece.

64. The method of claim 63, further comprising introducing a plasma into the chamber.

65. The method of claim 63, further comprising controlling a pressure in the chamber.

66. The method of claim 63, further comprising applying an electrical pulse to the peripheral portion of the surface of the microfeature workpiece.

67. The system of claim 63, further comprising applying an electrical pulse to the peripheral portion of the surface of the microfeature workpiece via a workpiece support.

68. The system of claim 63, further comprising:
introducing a plasma into the chamber; and
applying an electrical pulse to the peripheral portion of the surface of the microfeature workpiece via a workpiece support to cause an attractive force between selected particles in the plasma and the microfeature workpiece.

69. A method for making a plasma-based microfeature workpiece processing system for use in fabricating a microfeature workpiece, comprising:
configuring a workpiece support to support a peripheral portion of a surface of the microfeature workpiece;
placing the workpiece support in a chamber; and
positioning a clamping support having a dielectric material proximate to the workpiece support, the clamping support carrying a clamping electrode, the clamping electrode positioned so that when the peripheral portion of the surface of the microfeature workpiece is supported by the workpiece support the dielectric material is located between the clamping electrode and the microfeature workpiece.

70. The method of claim 69, further comprising configuring the chamber to include a gas distributor.

71. The method of claim 69, further comprising configuring the chamber to include a plasma generating device.

72. The method of claim 69, further comprising configuring the chamber to include a pressure control device.

73. The method of claim 69, further comprising placing an anode in the chamber.

74. The method of claim 69, further comprising configuring the clamping electrode to be couplable to an electrical source.

75. The method of claim 69, further comprising configuring the workpiece support to be couplable to an electrical source.

76. The method of claim 69 wherein configuring a workpiece support to support a peripheral portion of a surface of the microfeature workpiece includes configuring the workpiece support to conduct electrical current to the peripheral portion of the surface of the microfeature workpiece when the microfeature workpiece is carried by the workpiece support and the workpiece support is coupled to an electrical source.
